(19) United States
(12) Patent Application Publication
(10) Pub. No.: US 2011/0189438 A1
(43) Pub. Date: Aug. 4, 2011

(54) TEMPLATE, METHOD OF MANUFACTURING TEMPLATE, AND PATTERN FORMING METHOD

(76) Inventor: Kenji FURUSHO, Oita (JP)

(21) Appl. No.: 12/980,169

(22) Filed: Dec. 28, 2010

(30) Foreign Application Priority Data
Feb. 2, 2010 (JP) 2010-021029

(51) Int. Cl. B32B 3/30; B29C 33/40; B44C 1/22; C23C 14/04

(52) U.S. Cl. 428/156; 264/220; 216/44; 427/526

(57) ABSTRACT

According to one embodiment, first convex patterns and second convex patterns are provided in a mesa region of a template. The second convex patterns are provided spaced apart from the first convex patterns to have the height of bases equal to that of the first convex patterns. The height of the second convex patterns is different from that of the first convex patterns.

### CROSS-REFERENCE TO RELATED APPLICATIONS

This application is based upon and claims the benefit of priority from the prior Japanese Patent Application No. 2010-21029, filed on Feb. 2, 2010; the entire contents of which are incorporated herein by reference.

### FIELD

Embodiments described herein relate generally to a template, a method of manufacturing the template, and a pattern forming method.

### BACKGROUND

As a method of enabling integrated microfabrication in nano-order on a substrate, there is a nano-imprint technology. In the nano-imprint technology, pattern formation is performed by transferring irregularities formed on a template onto a substrate.

For example, National Publication of International Patent Application No. 2009-523312 and National Publication of International Patent Application No. 2007-521645 disclose a method of forming concave patterns in a two-stage structure as a template suitable for a dual damascene structure.

However, in the method disclosed in National Publication of International Patent Application No. 2009-523312 and National Publication of International Patent Application No. 2007-521645, because the concave patterns in the two-stage structure are arranged in the same place, the depths of the concave patterns transferred onto an organic material layer to be spaced apart from each other cannot be set different.

### BRIEF DESCRIPTION OF THE DRAWINGS

FIGS. 1A to 1C are sectional views for explaining a pattern forming method according to a first embodiment;

FIGS. 2A to 2C are sectional views for explaining a pattern forming method according to a second embodiment;

FIGS. 3A to 3D are sectional views for explaining a pattern forming method according to a third embodiment; and

FIGS. 4A to 4E are sectional views for explaining a method of manufacturing a template according to a fourth embodiment.

### DETAILED DESCRIPTION

In general, according to one embodiment, first convex patterns and second convex patterns are provided in a mesa region of a template. The second convex patterns are provided spaced apart from the first convex patterns to have the height of bases equal to that of the first convex patterns. The height of the second convex patterns is different from that of the first convex patterns.

Exemplary embodiments of a pattern forming method will be explained below in detail with reference to the accompanying drawings. The present invention is not limited to the following embodiments.

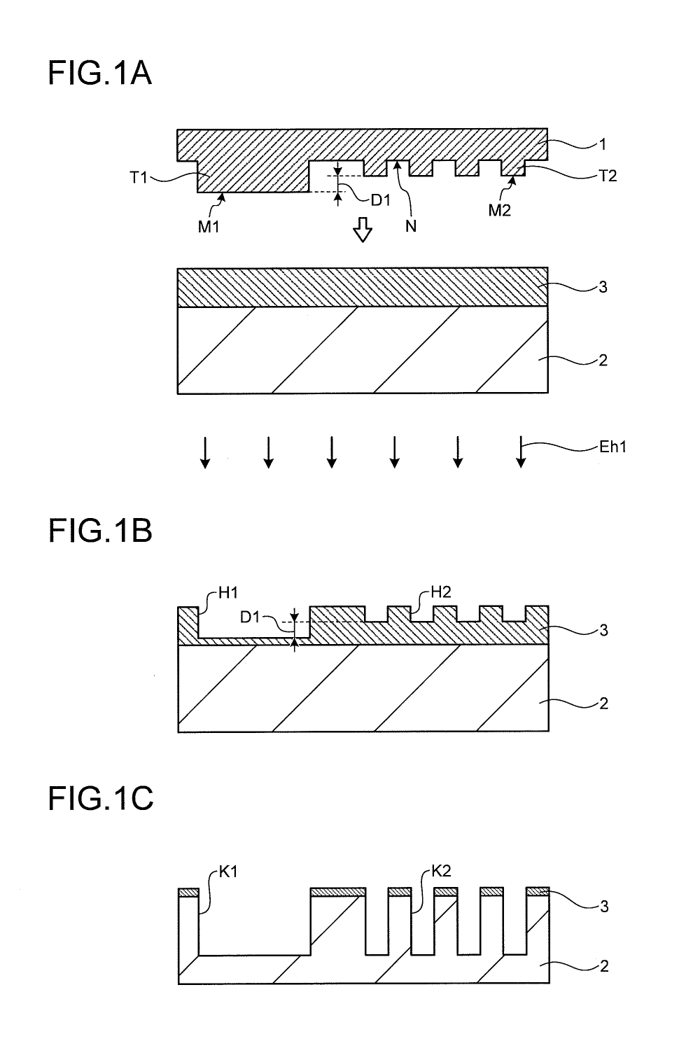

FIGS. 1A to 1C are sectional views for explaining a pattern forming method according to a first embodiment.

In FIG. 1A, convex patterns T1 and T2 arranged spaced apart from each other are provided in a mesa region of a template 1. The convex patterns T1 have height larger than that of the convex patterns T2 and have arrangement density smaller than that of the convex patterns T2. For example, an area of the distal ends of the convex patterns T1 can be set larger than an area of the distal ends of the convex patterns T2. Spaces among the convex patterns T1 can be set larger than spaces among the convex patterns T2.

The convex patterns T1 and the convex patterns T2 have equal height of bases N. Transfer surfaces M1 are provided at the tops of the convex patterns M1. Transfer surfaces M2 are provided at the tops of the convex patterns T2. A step D1 is provided between the transfer surfaces M1 and M2. The mesa region (a main pattern region) refers to a region in which a desired transfer pattern is formed in an irregular shape. When a plurality of patterns are transferred onto the same substrate to be processed 2, a peripheral region can be provided around the mesa region to prevent a pattern transferred earlier from being broken by interference between an adjacent pattern and a template in use. As a material of the template 1, when ultraviolet curing resin is used as a mask material 3, quartz or the like having permeability to an ultraviolet ray can be used. When thermosetting resin is used as the mask material 3, metal or the like having satisfactory thermal conductivity can be used as the material of the template 1. The step D1 between the transfer surfaces M1 and M2 is desirably set to cancel fluctuation in the depth of openings K1 and K2 due to a loading effect during processing of a substrate 2.

The mask material 3 is formed on the substrate 2. As the substrate 2, a semiconductor substrate, a glass substrate, a resin substrate, or the like can be used. The substrate 2 can be a wafer-like substrate, a film-like substrate, or a tape-like substrate. As the mask material 3, an organic material such as ultraviolet curing resin or thermosetting resin can be used.

Recesses H1 and H2 having different depths are formed in the mask material 3 by pressing the template 1 against the mask material 3 in a state in which the mask material 3 has flexibility (e.g., the mask material 3 is in a liquid state or a semisolid state) and transferring irregularities of the template 1 onto the mask material 3. When the mask material 3 is the ultraviolet curing resin, the mask material 3 can be hardened by irradiating an ultraviolet ray on the mask material 3 in a state in which the template 1 is pressed against the mask material 3. When the mask material 3 is the thermosetting resin, the mask material 3 can be hardened by heating the mask material 3 in the state in which the template 1 is pressed against the mask material 3.

The concave patterns H1 and H2 are pierced through the mask material 3 to form openings K1 and K2 in the substrate 2 by separating the template 1 from the mask material 3 and performing anisotropic etching Eh1 of the substrate 2 with the mask material 3 as a mask.

When the anisotropic etching of the substrate 2 is performed, an etching rate is different for a coarse pattern and a dense pattern because of a loading effect. The etching rate for the dense pattern is higher than the etching rate for the coarse pattern. Therefore, when the step D1 is not formed in the mask material 3, the openings K2 are deeper than the openings K1 and the depths of the openings K1 and K2 are non-uniform. In particular, when local coverage factors are extremely different, the non-uniformity of the depths of the openings K1 and K2 cannot be solved even if gas concentration during the anisotropic etching is adjusted.

On the other hand, the step D1 can be formed in the mask material 3 and the depth of the concave patterns H1 can be set larger than the depth of the concave patterns H2 by setting the height of the convex patterns T1 of the template 1 larger than the height of the convex patterns T2 of the template. Therefore, the thickness of the mask material 3 arranged on the openings K1 can be set smaller than the thickness of the mask material 3 arranged on the openings K2. The depth of the openings K2 etched deeper than the openings K1 because of the loading effect can be offset by the thickness of the mask material 3. In other words, residual layer thickness (RLT) as the thickness of a film remaining after imprint is changed according to a region, specifically, adjusted such that the residual film is smaller in a dense pattern region than in a coarse pattern region. The residual film indicates the thickness of the mask material 3 remaining on the bottom surfaces of the concave patterns formed in the mask material 3. As a result, even when the loading effect occurs when the anisotropic etching of the substrate 2 is performed, the depths of the openings K1 and K2 can be uniformalized.

In the embodiment explained above, the method of forming the openings K1 and K2 in the substrate 2 with the imprint technology is explained as an example. However, the present invention can also be applied to, for example, a method of forming a control gate electrode and a select gate electrode used in a NAND flash memory or the like with the imprint technology, can also be applied to a method of forming a wiring layer with the imprint technology, or can also be applied to a method of forming a via hole with the imprint technology.

In the embodiment explained above, the method of forming the two kinds of openings K1 and K2 having different densities in the substrate 2 is explained as an example. However, the present invention can also be applied to a method of forming three or more kinds of patterns having different densities. In this case, in a region having the smallest density, a transfer surface of the template 1 only has to be set highest. In a region having the second smallest density, the transfer surface of the template 1 only has to be set second highest. In a region having the largest density, the transfer surface of the template 1 only has to be set lowest. The height of the transfer surface of the template 1 can be set to correspond to fluctuation in an etching amount due to the loading effect.

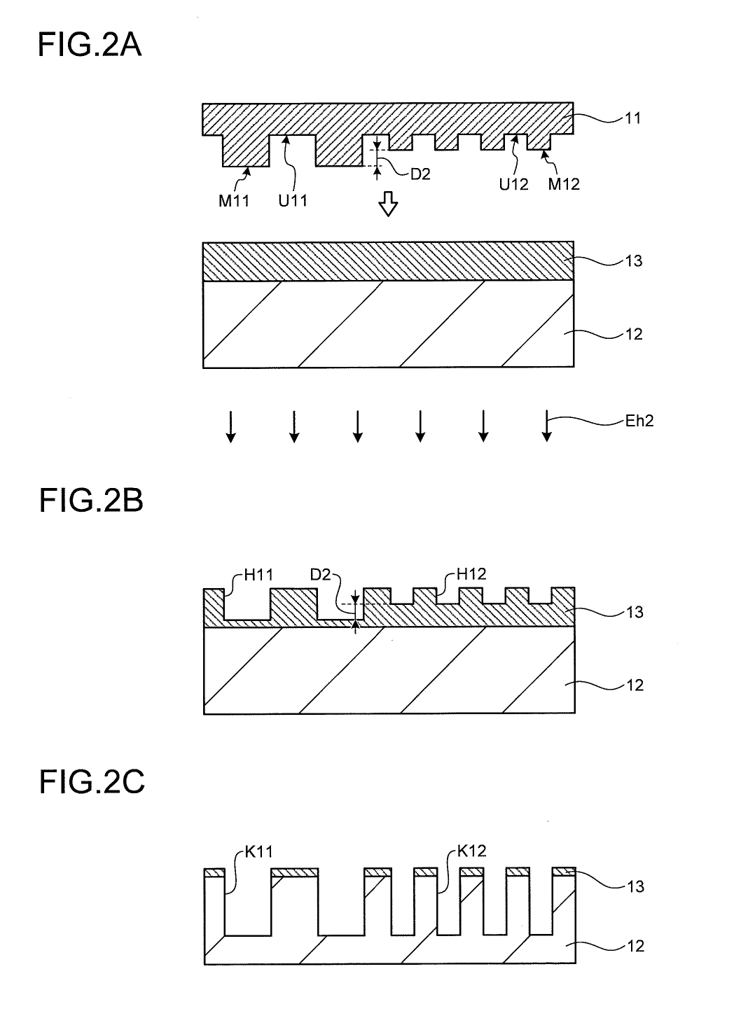

FIGS. 2A to 2C are sectional views for explaining a pattern forming method according to a second embodiment.

In FIG. 2A, transfer surfaces M11 and M12 are provided in a mesa region of a template 11. A step D2 is provided between the transfer surfaces M11 and M12 and the transfer surfaces M11 are set higher than the transfer surfaces M12. Recesses U11 and U12 arranged spaced apart from each other are respectively provided on the transfer surfaces M11 and M12. The concave patterns U11 have arrangement density smaller than that of the concave patterns U12. For example, an area of the bottoms of the concave patterns U11 can be set larger than an area of the bottoms of the concave patterns U12. Spaces among the concave patterns U11 can be set larger than spaces among the concave patterns U12.

The heights of the bottoms of the concave patterns U11 and U12 are equal to each other. The step D2 between the transfer surfaces M11 and M12 is desirably set to cancel fluctuation in the depth of openings K11 and K12 due to the loading effect during processing of a substrate 12. A mask material 13 is formed on the substrate 12.

The concave patterns H11 and H12 having the different depths are formed in the mask material 13 by pressing the template 11 against the mask material 13 in a state in which the mask material 13 has flexibility and transferring irregularities of the template 11 onto the mask material 13.

The concave patterns H11 and H12 are pierced through the mask material 13 to form the openings K11 and K12 in the substrate 12 by separating the template 11 from the mask material 13 in a state in which the mask material 13 is hardened and performing anisotropic etching Eh2 of the substrate 12 with the mask material 13 as a mask.

The depth of the concave patterns H11 can be set larger than the depth of the concave patterns H12 by providing the step D2 between the transfer surfaces M11 and M12. Even when the loading effect occurs, the depths of the openings K11 and K12 can be uniformalized.

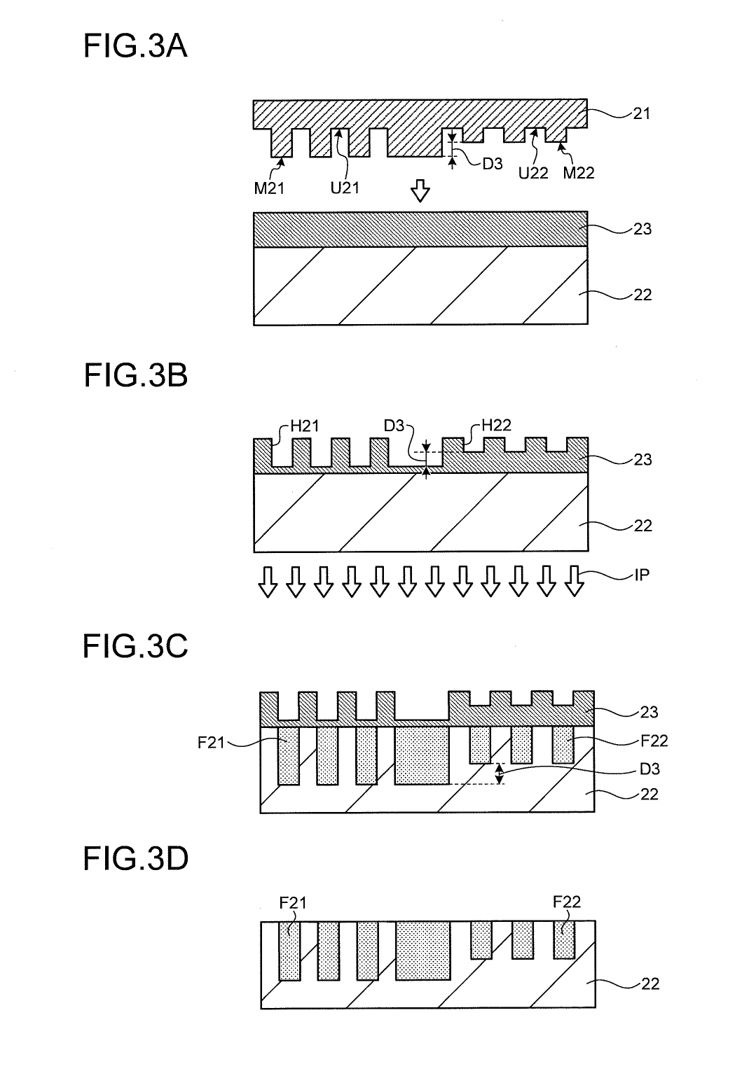

FIGS. 3A to 3D are sectional views for explaining a pattern forming method according to a third embodiment.

In FIG. 3A, transfer surfaces M21 and M22 are provided in a mesa region of the template 21. A step D3 is provided between the transfer surfaces M21 and M22. Recesses U21 and U22 arranged spaced apart from each other are respectively provided on the transfer surfaces M21 and M22. The heights of the bottoms of the concave patterns U21 and U22 are equal to each other. The step D3 between the transfer surfaces M21 and M22 is desirably adjusted according to a difference between the depths of impurity-introduced layers F21 and F22 formed on the substrate 22. A mask material 23 is formed on the substrate 22.

Recesses H21 and H22 having different depths are formed in the mask material 23 by pressing the template 21 against the mask material 23 in a state in which the mask material 23 has flexibility and transferring irregularities of the template 21 onto the mask material 23.

The impurity-introduced layers F21 and F22 are formed on the substrate 22 by separating the template 21 from the mask material 23 in a state in which the mask material 23 is hardened and performing ion implantation IP into the substrate 22 with the mask material 23 as a mask.

The depth of the concave patterns H21 can be set larger than the depth of the concave patterns H22 by providing the step D3 between the transfer surfaces M21 and M22. The impurity-introduced layers F21 and F22 having different depths can be formed by the ion implantation IP of the same energy.

Therefore, the ion implantation IP only has to be performed once to form the impurity-introduced layers F21 and F22 having the different depths. Because it is unnecessary to repeatedly perform the ion implantation IP according to the depths of the impurity-introduced layers F21 and F22, a manufacturing process can be simplified.

In the embodiment shown in FIGS. 3A to 3D, the method of forming the impurity-introduced layers F21 and F22 having the different depths by performing the ion implantation IP once is explained. However, the present invention can also be applied to a method of forming trenches or the like having different depths by performing an etching process once.

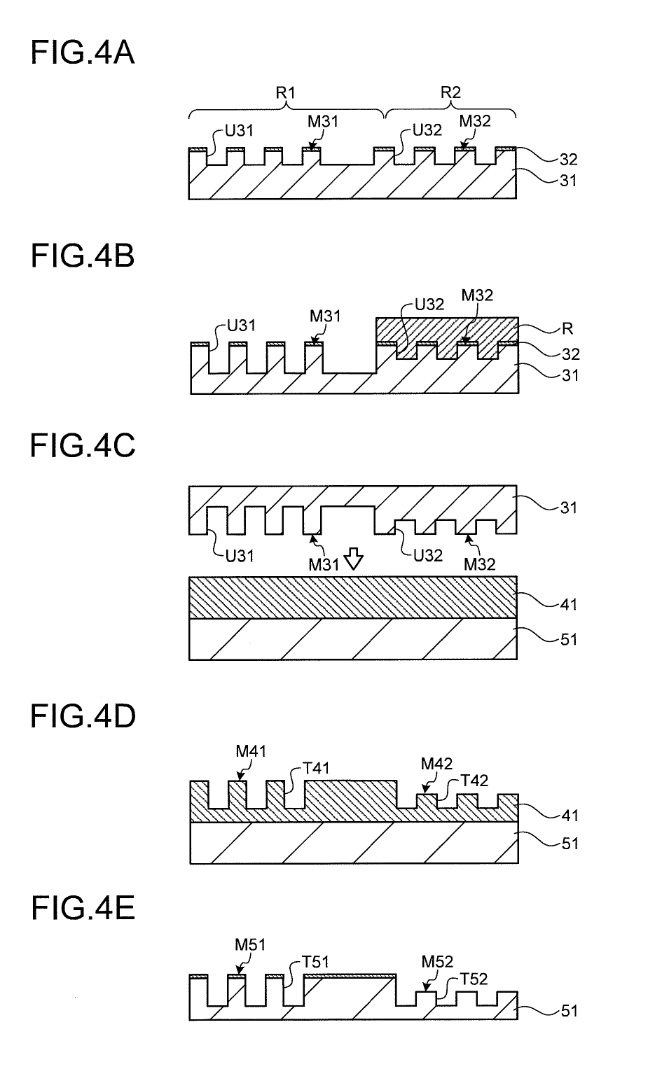

FIGS. 4A to 4E are sectional views for explaining a method of manufacturing a template according to a fourth embodiment.

In FIG. 4A, mesa regions R1 and R2 are provided on a template 31. Transfer surfaces M31 and M32 are respectively provided in the mesa regions R1 and R2. A shield layer 32 is formed on the template 31. The shield layer 32 is patterned by electron beam lithography. Recesses U31 and U32 having equal depths are respectively formed on the transfer surfaces M31 and M32 by performing anisotropic etching of the template 31 with the patterned shield layer 32 as a mask. As a material of the shield layer 32, for example, Cr can be used. When the template 31 is quartz, a fluorine radical can be used as an etching gas in the anisotropic etching of the template 31.

As shown in FIG. 4B, a resist film R is formed on the mesa region R2 by the photolithography technology. The depth of the concave patterns U31 is set larger than the depth of the concave patterns U32 by performing the anisotropic etching of the template 31 with the patterned shield layer 32 and the resist film R as a mask.

As shown in FIG. 4C, the shield layer 32 and the resist film R are removed from the template 31. As shown in FIG. 4D, convex patterns T41 and T42 having different heights are formed in a mask material 41 by pressing the template 31 against the mask material 41 on a template 51 and transferring irregularities of the template 31 onto the mask material 41. Transfer surfaces M41 are provided at the tops of the convex patterns T41 and transfer surfaces M42 are provided at the tops of the convex patterns T42.

As shown in FIG. 4E, convex patterns T51 and T52 having different heights are formed in the template 51 by performing the anisotropic etching of the template 51 with the mask material 41 as a mask. Transfer surfaces M51 are provided at the tops of the convex patterns T51 and transfer surfaces M52 are provided at the tops of the convex patterns T52. The anisotropic etching of the template 51 can be performed until the mask material 41 on the transfer surfaces M52 is completely removed and the height of the transfer surfaces M52 is reduced to be smaller than that of the transfer surfaces M51.

Consequently, it is possible to form the template 51 with the imprint technology from the template 31 formed by the electron beam lithography. It is possible to reduce manufacturing time for the template 51 including the convex patterns T51 and T52 having the different heights.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template comprising:
first convex patterns provided in a mesa region; and
second convex patterns provided in the mesa region spaced apart from the first convex patterns to have height of bases equal to that of the first convex patterns and having height different from that of the first convex patterns.

2. The template according to claim 1, wherein the first convex patterns have arrangement density smaller than that of the second convex patterns and have height larger than that of the second convex patterns.

3. The template according to claim 2, wherein an area of distal ends of the first convex patterns is larger than an area of distal ends of the second convex patterns.

4. The template according to claim 2, wherein spaces among the first convex patterns are larger than spaces among the second convex patterns.

5. A template comprising:
first transfer surfaces;
second transfer surfaces having a step provided with respect to the first transfer surfaces;
first concave patterns provided on the first transfer surfaces; and
second concave patterns provided on the second transfer surfaces to have height of bottoms equal to that of bottoms of the first concave patterns.

6. The template according to claim 5, wherein
the first concave patterns have arrangement density smaller than that of the second concave patterns, and
the first transfer surfaces have height larger than that of the second transfer surfaces.

7. The template according to claim 6, wherein an area of the bottoms of the first concave patterns is larger than an area of the bottoms of the second concave patterns.

8. The template according to claim 6, wherein spaces among the first concave patterns are larger than spaces among the second concave patterns.

9. A method of manufacturing a template comprising:
forming a first template in which concave patterns having different depths are provided in a mesa region; and
transferring irregularities provided in the mesa region of the first template to thereby form a second template in which convex patterns having different heights are provided in a mesa region.

10. The method of manufacturing a template according to claim 9, wherein the concave patterns having different heights are formed in the first template by setting etching amounts for forming the concave patterns different from one another.

11. A pattern forming method comprising:
pressing a template, in which convex patterns having different heights from bases are provided in a mesa region, against a mask material to thereby form concave patterns having different depths in the mask material; and
performing etching of a substrate with the mask material, in which the concave patterns having the different depths are formed, as a mask.

12. The pattern forming method according to claim 11, wherein the heights of the convex patterns are different according to a coverage factor by a pattern formed on the substrate by the etching.

13. The pattern forming method according to claim 12, wherein the heights of the convex patterns are large in a region where density of the pattern is small compared with a region where the density of the pattern is large.

14. The pattern forming method according to claim 11, wherein, when the template is pressed against the mask material, the mask material is in a state in which the mask material has flexibility.

15. The pattern forming method according to claim 14, wherein the mask material is hardened after the template is pressed against the mask material.

16. The pattern forming method according to claim 11, wherein the concave patterns are pierced through the mask material when the etching of the substrate is performed.

17. The pattern forming method according to claim 11, wherein the heights of the convex patterns are reduced by depth of the concave patterns etched deeper in a depth direction by a loading effect.

18. A pattern forming method comprising:
pressing a template, in which convex patterns having different heights from bases are provided in a mesa region, against a mask material to thereby form concave patterns having different depths in the mask material; and
performing ion implantation into a substrate with the mask material, in which the concave patterns having the different depths are formed, as a mask.

19. The pattern forming method according to claim 18, wherein the heights of the convex patterns are large in a region where depth of the ion implantation is large compared with a region where the depth is small.

20. The pattern forming method according to claim 19, wherein impurity-introduced layers having different depths are formed on the substrate by performing the ion implantation once with same energy.
